(19) United States
(12) Patent Application Publication
(10) Pub. No.: US 2022/0382944 A1
(43) Pub. Date: Dec. 1, 2022

(54) EXTENDED INTER-KERNEL COMMUNICATION PROTOCOL FOR THE REGISTER SPACE ACCESS OF THE ENTIRE FPGA POOL IN NON-STAR MODE

(71) Applicant: Intel Corporation, Santa Clara, CA (US)

(72) Inventors: Han YIN, Beijing (CN); Xiaotong SUN, Beijing (CN); Susanne M. BALLE, Hudson, NH (US)

(21) Appl. No.: 17/327,210

(22) Filed: May 21, 2021

(51) Int. Cl. G06F 30/331; G06F 13/12; H04L 29/12

(52) U.S. Cl. CPC G06F 30/331; G06F 13/126; H04L 61/6022

(57) ABSTRACT

Methods and apparatus for an extended inter-kernel communication protocol for discovery of accelerator pools configured in a non-star mode. Under a discovery algorithm, discovery requests are sent from a root node to non-root nodes in the accelerator pool using an inter-kernel communication protocol comprising a data transmission protocol built over a Media Access Control (MAC) layer and transported over links coupled between IO ports on accelerators. The discovery requests are used to discover each of the nodes in the accelerator pool and determine the topology of the nodes. During this process, MAC address table entries are generated at the various nodes comprising (key, value) pairs of MAC IO port addresses identifying destination nodes and that may be reached by each node and the shortest path to reach such destination nodes. The discovery algorithm may also be used to discover storage related information for the accelerators. The accelerators may comprise FPGAs or other processing units, such as GPUs and Vector Processing Units (VPUs).

### BACKGROUND INFORMATION

In recent years, Artificial Intelligence (AI) and Deep Learning (DL) research have seen explosive growth thanks to the increase in computing capability generated by the availability of accelerators such as graphics processing units (GPUs) and Field Programmable Gate Arrays (FPGAs). AI and DL models are getting deeper each year requiring an increase in computational resources as well as storage for model parameters. Pools of nodes and accelerators are therefore a logical way forward to keep up with the research and trends.

Applications such as Genomics, Video Streaming, and DL inference can be pipelined and architected to decouple the FPGA kernel execution from the host CPU to allow the FPGA kernels to communicate directly with each other. Molecular Dynamics is also conducive to using direct FPGA-to-FPGA communication as the workload is mapped onto 2D or 3D Torus for efficiency between node communication.

Direct inter-FPGA communication allows for lower latency execution between FPGAs since it does not communicate through the CPU software stack, PCI Express (PCIe), and does not use CPU resources. Furthermore, the FPGAs can be clustered together to allow them to work on a single problem by forming device pipelines or other topologies thereby scaling the application's performance and functionality without the need for a larger FPGA.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram illustrating an example of an FPGA pool constructed in a star mode;

FIG. 2 is a diagram illustrating an example of an FPGA pool constructed in a non-star mode;

FIG. 3 is a diagram illustrating a node representation of the FPGA pool of FIG. 2;

FIG. 4 is a flowchart illustrating operations performed by a discovery algorithm, according to one embodiment;

FIG. 5 is a flowchart illustrating an FPGA process flow when receiving a discovery request, according to one embodiment;

FIG. 6 shows the key fields of the extended IKL header of different request and response packets;

FIG. 7 is a flowchart illustrating the FPGA process flow when receiving a discovery response, according to one embodiment;

FIG. 8a is a diagram illustrating a first loop of a discovery algorithm under which a host server sends a discovery request to a root node;

FIG. 8b is a diagram illustrating a second loop of the discovery algorithm under which node 1 is discovered;

FIG. 8c is a diagram illustrating a third loop of the discovery algorithm under which node 2 is discovered;

FIG. 8d is a diagram illustrating a fourth loop of the discovery algorithm under which node 3 is discovered;

FIG. 8e is a diagram illustrating a fifth loop of the discovery algorithm under which edges of an alternate path to node 3 are discovered;

FIG. 8f is a diagram illustrating a sixth loop of the discovery algorithm under which node 4 is discovered;

FIGS. 8g, 8h, are diagrams illustrating respective stages in a loop of the discovery algorithm under which terminated NICs are discovered;

FIG. 9a is a diagram illustrating an entry for a MAC address table generated by the root node in connection with performing the first loop of FIG. 8a;

FIG. 9b is a diagram illustrating entries written to MAC address tables for the root node 0 and ‘node 1 in connection with discovering node 1 in FIG. 8b;

FIG. 9c is a diagram illustrating entries written to MAC address tables for the root node 0 and ‘node 2 in connection with discovering node 2 in FIG. 8c;

FIG. 9d is a diagram illustrating entries written to MAC address tables for the root node 0, node 1, and ‘node 3 in connection with discovering node 3 in FIG. 8d;

FIG. 9e is a diagram illustrating entries written to MAC address tables for the root node 0, node 2, and ‘node 3 in connection with discovering the alternative path to node 3 in FIG. 8e;

FIG. 9f is a diagram illustrating entries written to MAC address tables for the root node 0, node 1, node 3, and node 4 in connection with discovering node 4 in FIG. 8f.

FIG. 10 is a schematic diagram illustrating an FPGA Programmable Accelerator Card (PAC), according to one embodiment;

FIG. 10a is a schematic diagram illustrating an accelerator card, according to one embodiment;

FIG. 11 is a schematic diagram of a conventional physical rack configuration in a data center;

FIG. 12 is a schematic diagram of a Rack Scale Design (RSD) configuration in a data center, according to one embodiment;

FIG. 13 is a block diagram of an RSD management architecture, according to one embodiment;

FIG. 14 is a schematic diagram illustrating an embodiment of a pooled accelerator drawer or sled; and

FIG. 15 is a schematic diagram illustrating an embodiment of a pooled FPGA drawer under which FPGAs are coupled via cables.

### DETAILED DESCRIPTION

Embodiments of methods and apparatus for an extended inter-kernel communication protocol for the register space access of FPGA pools configured in a non-star mode are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In the modern data center, using a remote FPGA pool to accelerate service processing and increase throughput has become a growing interest for more and more developers. In such cases, multiple remote FPGAs decouple a common workload to different work items from the host server, then pipeline them to obtain higher performance (e.g., increased throughput and/or reduced workload latency). To support this implementation, the key technology is the inter-kernel communication protocol which provides a low-latency and high bandwidth streaming protocol for direct FPGA to FPGA communication over ethernet. But the disadvantage of the protocol is that, if the FPGA pool is constructed in non-star mode and without an ethernet switch, the host server cannot configure all the other FPGAs within the pool, except the root FPGA.

In accordance with aspects of the embodiments disclosed herein, an extended inter-kernel communication protocol for FPGA pools configured in the non-star mode is provided as a solution to this problem. In one aspect, the extended inter-kernel communication protocol is an extension to the Inter-Kernel Links (IKL) protocol, which is low latency and high bandwidth streaming protocol and architecture with built-in reliability and control flow for direct inter-FPGA communication. It was introduced in Balle, S. M., Tetreault, M., & Dicecco, R. Inter-Kernel Links for Direct Inter-FPGA Communication. Using IKL, developers can design applications in OpenCL™, high-level synthesis (HLS), or register transfer level (RTL) that use direct inter-FPGA communication using off-the-shelf Intel® FPGA Programmable Acceleration Cards (Intel® FPGA PACs) available in the data center. Users can pipeline tasks within an application to run on multiple FPGAs as well as partition their designs between FPGAs thereby increasing their overall available resources. IKL can also be used for Inter-Kernel communication between other types of accelerators employing Kernel communication, such as GPUs, and Vector Processing Units (VPUs), as well as other XPUs, as discussed below.

### IKL Packet Header and Constructed Mode of FPGA Pool

The original IKL protocol is designed and built over the MAC (Media Access Control) layer for packets to be transmitted between two NICs (Network Interface Controllers) (or NIC ports) on different FPGA cards. The IKL header includes fields specifying packet type, routing information, reliability and flow control. The detailed IKL header format is shown in TABLE 1.

TABLE 1

| Bits | Name |
|---|---|
| 00:47 | dst_mac_addr [00:47] |
| 48:95 | src_mac_addr [00:47] |
| 96:111 | type or length [00:15] |
| 112:115 | packet_type [00:03] |
| 116 | credit_pool |
| 117 | retransmitted |
| 118:119 | reserved [00:01] |
| 120:127 | bus_ack_seq_no [00:07] |
| 128:135 | bus_seq_no [00:07] |
| 136:151 | src_domain_id [00:15] |
| 152:163 | port_ack_seq_no [00:11] |
| 164:175 | port_pkt_seq_no [00:11] |
| 176:191 | port_credit_limit [00:15] |
| 192:199 | src_sled_id [00:07] |
| 200:207 | src_FPGA_id [00:07] |
| 208:215 | src_AFU_id [00:07] |
| 216:223 | src_port_id [00:07] |
| 224:231 | dst_sled_id [00:07] |
| 232:239 | dst_FPGA_id [00:07] |
| 240:247 | dst_AFU_id [00:07] |
| 248:255 | dst_port_id [00:07] |
| 256:max | IKL payload, max 1472 bytes |

The first 14 bytes from bits 0 to bits 111 are the common MAC header. For every FPGA within the FPGA pool, the source MAC address can be generated from the unique device ID through certain hash algorithms. In cases where an FPGA has multiple NICs or multiple NIC ports, each NIC/NIC port will have its own MAC address. The “type or length” field of the MAC header is fixed to 0×5042 to identify the following IKL protocol.

Bits 112 begins the portion of the IKL header. In the IKL header, the first 4 bits indicate the IKL packet type. The IKL protocol includes specific packet types for data transmission, flow control and port credit update. This field may also indicate different commands type.

The routing information is from bits 192 to bits 255. The total 8 bytes can be divided into two similar parts, where the first 4 bytes indicate the ID relative information of the source FPGA while the last 4 bytes indicate the same information for the destination FPGA. When performing data transmission through IKL protocol, the FPGA filters the destination ID information of every ingress packet.

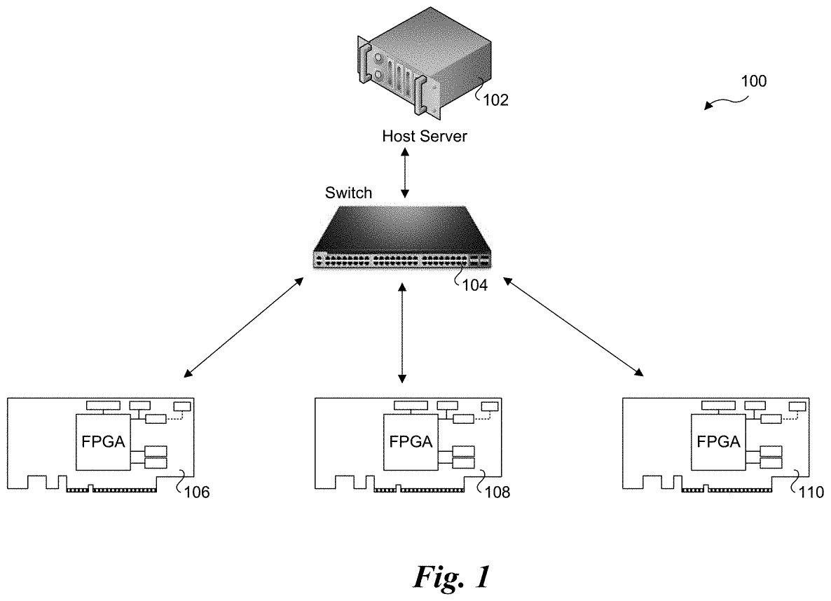

The IKL protocol supports two constructed modes of FPGA pools: the star mode and the non-star mode. As example of an FPGA pool constructed in the star mode is shown in system 100 of FIG. 1. Each of a host server 102, and FPGA cards 106, 108, and 110 are connected to a switch 104, such as an Ethernet switch. Thus, software running on host server 102 can configure the FPGAs on any of FPGA cards 106, 108, and 110 directly over switch 104 using an applicable network protocol, such as FPGA-over-Fabric (FPGA-oF) protocol. To support communication between host server 102 and an FPGA card, the FPGA card decapsulates the packet and analyzes the particular protocol.

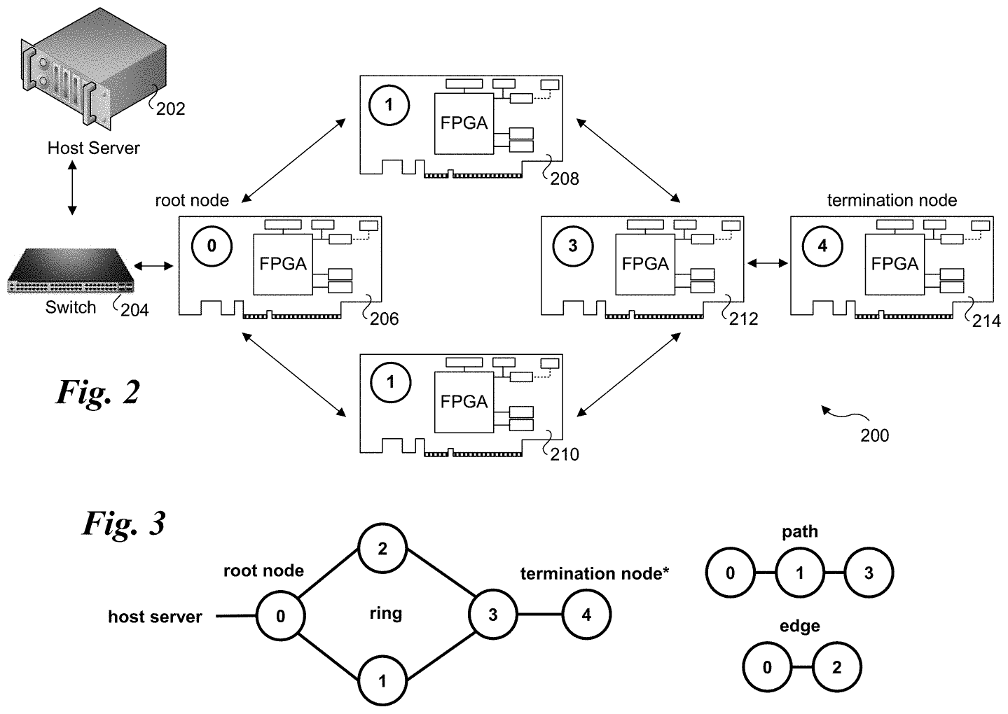

As example of an FPGA pool constructed in the non-star mode is shown in system 200 of FIG. 2. System 200 includes a host server 202 coupled and a root FPGA card 206 coupled to a switch 204. Root FPGA card 206 is coupled to each of FPGA cards 208 and 210, which in turn are coupled to an FPGA card 212. FPGA card 212 is also connected to an FPGA card 214.

Under a non-star mode, the host server can only configure the root FPGA. As for the other FPGAs within the FPGA pool (e.g., the FPGAs on FPGA cards 208, 210, 212, and 214), the root FPGA must translate the FPGA-oF commands into IKL packets, then forward the IKL packet to the destination FPGAs. As a result, the IKL protocol needs to support not only the data transmission, but also the command transmission.

### FPGA Storage Space and Extended IKL Protocol

The FPGA storage space includes memory and register space. The memory is usually used for data transmission between FPGAs in the IKL protocol, while the register space is usually used for command transmission. To support command transmission, the IKL protocol must be extended—this is referred to as the extended IKL protocol herein. Regardless of memory and register space, the entire storage space can be divided into several regions. There are certain attributes to describe each region. The attributes used for describing regions in one embodiment of the extended IKL protocol are shown in TABLE 2.

TABLE 2

| Attributes | Description |
|---|---|
| Region Type | data/control; means memory/register space access |
| Region Number | unique region ID |
| Region Start Address | the start physical address of this region |
| Region Size | the total length in bytes of this region |

The attributes in TABLE 2 include a Region Type, a Region Number, a Region Start Address, and a Region Size. The Region Type is used to identify whether the region is used for data (memory access) or control (register space access). The Region Number specifies a unique region Identifier (ID). The Region Start Address and Region Size attributes respectively specify the starting physical address for the region and the length in bytes of the region.

Users may also define their own custom attributes. For example, the Region Type attribute may include addition region types like buffer and kernel. In addition, additional region attributes may be specified.

When trying to access a specific region address in data or command transmission, an address offset and the total length are required. To facilitate this additional information, an extended IKL header is provided, an embodiment of which is shown in TABLE 3.

TABLE 3

| Bits | Name | Description |
|---|---|---|
| 256:263 | region_type [00:07] | type of the region being accessed |
| 264:271 | region_num [00:07] | unique ID of the region being accessed |
| 272:335 | region_offset [00:63] | offset of the region or the absolute region address |
| 336:367 | data_length [00:31] | total length in bytes of IKL payload in this packet |

In addition to the region_type and region_num attributed, the new attributes for the extended IKL header are the region_offset (the offset of the region or the absolute region address) and the data_length (the total length in bytes of IKL payload in this packet).

Besides the foregoing extended fields in the IKL header, some of the original IKL header fields are also modified to support command transmission. Firstly, the packet type field is only meaningful when value is 0 to 2, so the reserved value 3 to 15 are modified to identify the different command type. Next, for every command request, a response packet is needed. Then the reserved 2 bits are used to indicate whether the packet is a request or response. Finally, the unused source domain ID field is divided into two parts, the first 8 bits are defined as previously, but the last 8 bits are modified to indicate the status of a command response. TABLE 4 shows details of the modified fields, in one embodiment.

TABLE 4

| Bits | Name | Description | |
|---|---|---|---|
| | | Value | Type |
| 112:115 | packet type [00:04] | 0-2 | keep previous define |
| | | 3 | discovery |
| | | 4/5 | register read/write |
| | | 6-15 | reserved |
| | | b′01 = request, b′10 = response | |
| | | keep previous define, also not in use | |
| | | Value | Description |
| 118:119 | dir flag [00:01] | 0 | success |
| 136:143 | src domain id [00:07] | 1 | new edge, only for discovery command |
| 144:151 | status code [00:07] | 2 | terminate, only for discovery command |
| | | 3-255 | reserved |

Based on the extended IKL protocol, the root FPGA can translate both data and command transmission into IKL packets. With the MAC address table built in the discovery process (described below), the root FPGA can look up the MAC address of the specific FPGA and fill the MAC header. Then the IKL packets can be forwarded between different FPGAs and to be received by the correct (destination) FPGA.

### Discovery Algorithm and MAC Address Table

In the non-star mode, a discovery algorithm is used to determine the FPGA pool topology and configuration information. The discovery algorithm is implemented for three reasons. First, it is used to help the host server collect the storage related information of FPGAs, which are not directly connected to the Ethernet switch. Second, the topology of the FPGA pool is also collected so that the host server can design the proper FPGA acceleration architecture for its workload. Third, each FPGA within the pool builds a MAC address table during the discovery process that contains MAC address information used for packet forwarding.

The topology of a FPGA pool can be viewed as an undirected graph. Then the basic principle of discovery algorithm is to utilize breadth first search (BFS) algorithm to traverse every FPGA within the FPGA pool. Once the root FPGA receives the discovery command from the host server, it will act as the root node and cyclically send requests to discover all possible paths. In each loop, when a new FPGA node or edge (direct connection between two FPGAs) is discovered, a response packet is generated and sent back to the root node.

Sometimes, the discovery loop will find a termination node. Then a response packet with specific status field will be returned to the previous node in the path. At that time, the previous node will mark the NIC, which receives the response, as a termination NIC. And when all the NICs of the root node are unavailable or terminated, the discovery process is complete.

In an FPGA pool with complex topology, the abstracted graph may contain rings. A mechanism for finding the rings is introduced below. If a ring is detected, the relative node will also reply to the previous node, then both NICs that send or receive the response packet will be marked as termination NICs.

FIG. 3 shows some basic concepts of the discovery algorithm. Each FPGA is associated with a node number that also operates as an identifier (ID), with the root node allocated a node number and ID of ‘0’. The remaining nodes ‘1’, 2’, ‘3’, and ‘4’ are non-root nodes, with node ‘4’ being a termination node. A pair of nodes is connected by an “edge.” Three or more nodes are connected by a “path.”

During the process of request-response, each FPGA node in the path records the source MAC address of the request or response, then binds it to the local MAC address of corresponding NIC. The root node records the source FPGA ID of the response packet in its MAC address table, and addition to binding the source MAC address of the NIC.

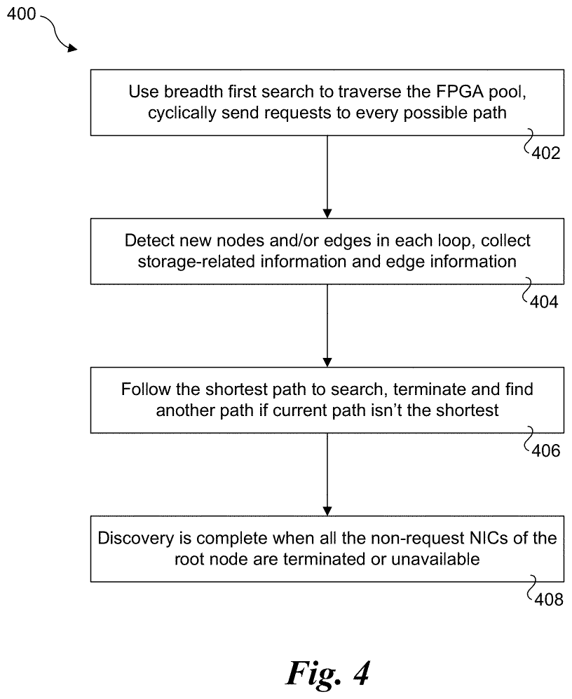

FIG. 4 shows a flowchart 400 illustrating high-level operations that are performed by the discovery algorithm. As shown in a block 402, breadth first searching is used to traverse the FPGA pool under which requests are cyclically sent to every possible path. In a block 404, new nodes or edges are detected in each loop, and storage related information and edge information is collected. As shown in a block 406, the shortest path to search is followed. The current path is terminated, and another path is found if the current path is not the shortest path. As shown in a block 408, discovery is complete when all the non-request NICs of the root node are terminated or unavailable.

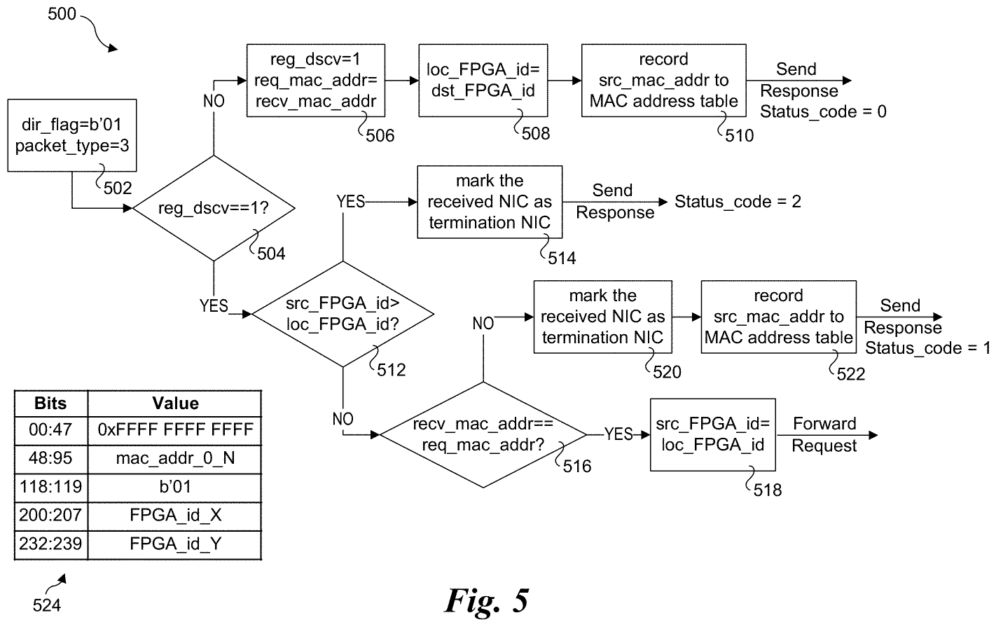

FIG. 5 shows a flowchart 500 illustrating an FPGA process flow when receiving a discovery request. Besides some fields in the extended IKL header, some abbreviations are used in flowchart 500 to simplify the expression.

“reg_dscv” is a register that indicates whether this FPGA is discovered. At the first time of receiving a discovery request, the FPGA will set “reg_dscv” register to 1.

“req_mac_addr” is the MAC address of the NIC that first receives a discovery request. Since the BFS algorithm is used for discovery, this MAC address is the destination MAC address if the root node wants to send a request to the specific FPGA through the shortest path.

“recv_mac_addr” is the MAC address of the NIC that receives the request or response.

“loc_FPGA_id” is a register that stores the unique FPGA ID. At the first time of receiving a discovery request, the FPGA will save the destination FPGA ID field to this register.

“mac_addr_X_Y” is the MAC address of the Y^{th} NIC of the FPGA with FPGA ID X.

“FPGA_id_X” is the unique FPGA ID with value X. The root node (root FPGA) always has an ID ‘0’. When the root node sends a discovery request, it will set the destination FPGA ID field to the ID discovered in the next loop. For example, after the root node is discovered and has an ID ‘0’, the root node wants to discover a FPGA with ID ‘1’. Then the destination FPGA ID field is set to ID ‘1’.

When processing the discovery request, the FPGA first checks whether it has been previously discovered. If not, the FPGA will directly send a response with status_code=0 through the NIC that receives the discovery request. If the FPGA has already been discovered, it will further check whether the source FPGA ID field is larger than the unique FPGA ID in its local register (the local FPGA ID). If this is TRUE (YES), it means the discovery process has fallen into a ring and another path needs to be tried by sending a response with a status_code=2. In the BFS-based discovery algorithm, the source FPGA ID is set to the ID of previous node in the path and the previous node ID is always smaller in the shortest path. If source FPGA ID is smaller, then the FPGA needs to check whether the MAC address of the NIC, which receives the discovery request, is the previous NIC that first receives the request. If not, this means another new edge is discovered and the root node has another path to send request to this FPGA. A response with status_code=1 is then sent to the root node through the NIC that receives the request. If yes, the FPGA needs to select an available, un-terminated and non-request NIC to forward the discovery request based on the BFS algorithm. Of course, if no NICs meet the requirements, this FPGA becomes a termination node and send a response with status_code=2 to the previous node in the path.

Logic for implementing the foregoing operations is presented in flowchart 500 of FIG. 5. The process begins in a block 502 in which the dir_flag is set to a binary value of ‘01’ and the packet type is set to 3. In a decision block 504 a determination is made to whether the reg_dscv value is ‘1’, which indicates whether the FPGA has been previously discovered. If this is the first time an FPGA has received a discovery request packet the answer will be NO, and the logic will proceed to a block 506 in the reg_dscv is set to 1, and the requester MAC address (req_mac_addr) is set to the receiver MAC address (recv_mac_addr). In a block 508 the local FPGA ID (loc_FPGA_id) is set to the destination FPGA ID (dst_FGPA_ID). The source MAC address (src_mac_addr) is then recorded in the MAC address table in a block 510, and the FPGA sends a response via its NIC with a status_code=0 back to the root node.

Returning to decision block 504, if the node has already been discovered it will have previously set its discovery register (reg_dscv) value to 1 (e.g., in block 506), and the answer to decision block 504 will be YES. The logic will then proceed to a decision block 512 in which a determination is made to whether the source FPGA ID is greater than the local FPGA ID. If the answer is YES, the logic proceeds to a block 514 in which the received NIC is marked as a termination NIC. A response is then sent back to the root node with status_code=2.

If the answer to decision block 512 is NO, the logic proceeds to a decision block 516 in which a determination is made to whether the receiver MAC address matches the requester MAC address. If these addresses match, the answer is YES and the logic proceeds to a block 518 in which the source FPGA ID is set to the local FPGA ID. The request is then forwarded to a next node. If the receiver MAC address and the requester MAC address do not match, the logic proceeds to a block 520 in which the received NIC is marked as a termination NIC. The source MAC address is then recorded in the MAC address table for the node in a block 522, followed by the node sending it response with a status_code=1 to the root node.

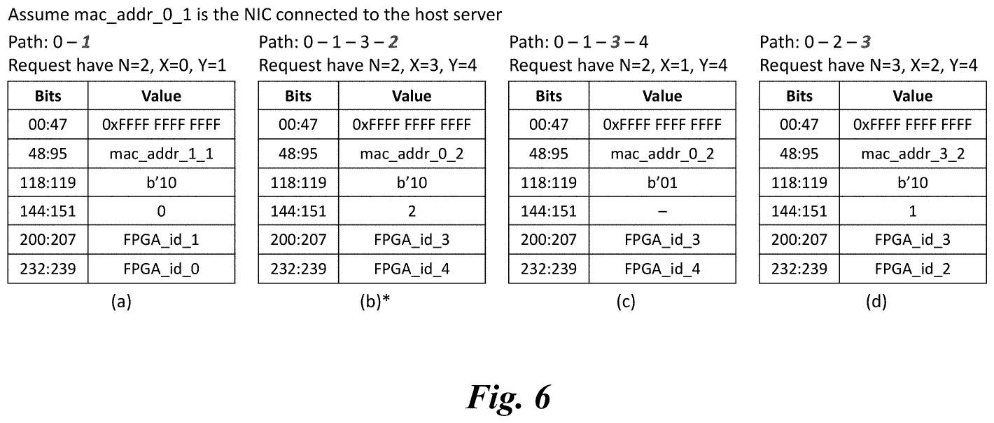

Assume the request packet sent from the root node is the one in FIG. 5 (then have X=0) and the topology of the FPGA pool is that shown in FIG. 3. FIG. 6 shows the key fields of the extended IKL header of different request and response packets. The number in bold is the FPGA node receiving the request.

In FIG. 6, table (a) and (d) respectively show the response packets when discovering a new FPGA node and a new edge. To generate the response, the FPGA needs to exchange the source FPGA ID and destination FPGA ID field, then set the source MAC address field to the MAC address of the NIC that received the request, and finally set the status code and direction flag field. Each time a new FPGA node is discovered, the response (table (a)) will also contain the storage related information in the payload field of the extended IKL header. TABLE 5 shows the key fields in such a case.

TABLE 5

| Bits | Value |
|---|---|
| 00:47 | 0xFFFF FFFF FFFF |
| 48:95 | mac_addr_1_1 |
| 144:151 | 0 |
| 200:207 | FPGA_id_1 |
| 232:239 | FPGA_id_0 |
| 336:367 | 1 + N × 14 |
| 368:375 | N; total number of regions |
| 376:383 | data/control; region type |
| 384:391 | 0; unique region number |
| 392:455 | start_addr_0; start address |
| 456:487 | size_0; region size |
| . . . | repeat the 14 bytes for N times |

The payload of the extended IKL header begins at Bit 368 (not shown).

The payload of the extended IKL header begins at Bit 368. The first byte of the payload is the total number of regions, N. The remaining fields in the payload are the attributes of each region; these are similar to the attributes in TABLE 2 described above. 14 bytes are used to describe all the region attributes listed in TABLE 2, so the total length of the extended IKL payload is (1+N×14) bytes.

As discussed in further detail below, the response packet of a newly discovered FPGA will be directly forward to the root node. As a result, the root FPGA is able to collect all the storage related information of each FPGA within the FPGA pool during the discovery process. At the same time, the edge between the new node and its previous node in the search path is also identified with corresponding information being returned to the root FPGA via a response packet, thus enabling the root FPGA to identify any new edge nodes. A new edge can be ascertained since the source FPGA ID field is the newly discovered FPGA ID and the destination FPGA ID is its previous FPGA ID.

The differences between the response packet for discover of a new node and a new edge are the latter doesn't have a payload field, and the source FPGA ID field is set to the local unique FPGA ID rather than the destination FPGA ID of the request packet. With all the edge information collected in the process of discovering the new node and new edge, the root FPGA can determine the topology of the FPGA pool.

In FIG. 6, table (b) shows the response packet when discovering a termination node or the search process falls into a ring. Without any operation to the ID fields and MAC address fields, the operations to generate the response are setting the status code and direction flag fields.

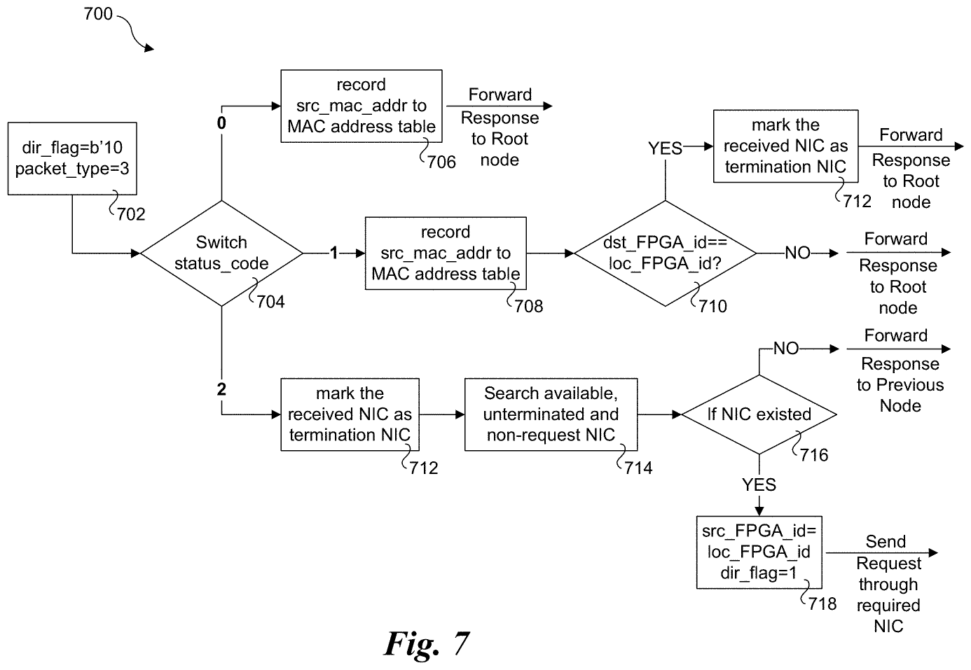

FIG. 7 shows a flowchart 700 illustrating the FPGA process flow when receiving a discovery response, according to one embodiment. In a block 702, the dir_flag is set to a binary value of ‘10’ and the packet_type is set to 3. The FPGA first needs to check the status code field of the response packet, which is determined in a decision block 704, where the status code is either 0, 1, or 2. A status code value of 0 indicates a new FPGA node has been discovered. Accordingly, the source MAC address (src_mac_add) is recorded to the MAC address table for the node in a block 706, and the response is forwarded to the root node. In this instance, the FPGAs in the search path only need to directly forward the response packet to the root node, without taking any further action for the response packet.

A status_code value of 1 indicates a new edge node has been discovered. Accordingly, in a block 708 the source MAC address (src_mac_addr) is recorded in the MAC address table for the node. Before the FPGA forwards the response packet to the root node, it marks the NIC that receives the response packet as the termination NIC (block 712) when the destination FPGA ID is equal to the local unique FPGA ID, as determined in a decision block 710. If the destination FPGA ID and local FPGA ID are not equal, the response is forwarded to the root node without marking the received NIC as a termination NIC.

As discussed above, it is preferred to search for new FPGAs through the shortest path. Returning to decision block 704, a status_code value of 2 indicates the current search path needs to be terminated. As shown for path ‘2’, in a block 212 the FPGA first marks its NIC as a termination NIC, and then search in a block 714 whether an available, un-terminated and non-request NIC existed or not. “Exist” means the node has at least one NIC than is an available. un-terminated and non-request NIC/NIC port. “Available” means the NIC port connects to another NIC port through a cable or fiber. “Un-terminated” means the NIC port has not been marked as a termination NIC. “Non-request” means the NIC port is not the NIC port that first receives a discovery request.

As shown in a decision block 716, if the required NIC existed, the answer is YES and the FPGA sets the direction flag (dir_flag=1), sets the source FPGA ID field to the local FPGA ID, and then sends the request through the required NIC. “Required” here means the NIC that meets the requirements (available, un-terminated and non-request). If the NIC did not exist, the FPGA forwards the response to its previous FPGA node in the search path.

Table (c) in FIG. 6 shows the forwarded request. As shown in block 518 of FIG. 5 and presented above, the only operation to generate the forwarded request is to set the source FPGA ID field to the local unique FPGA ID. Through this operation, the newly discovered node ID is always bound with the ID of its previous node in the search path, which we already know in the previous loops. In other words, we always know how the search paths “spread” in the FPGA pool.

Through use of the request and response process flows in FIG. 5 and FIG. 7, the root FPGA is enabled to collect all the storage related information of the entire FPGA pool, together with the pool's topology. Each FPGA within the pool will build its own MAC address table during the discovery process. As presented in FIGS. 5 and 7 above, the FPGA records the source MAC address field in its MAC address table during the process of discovering a new node or new edge. The root FPGA also records the source FPGA ID field, since the host server only knows the FPGA ID of the root FPGA and the root FPGA needs to find the corresponding MAC address when translating host commands into extended IKL packets.

### Example Discovery Process

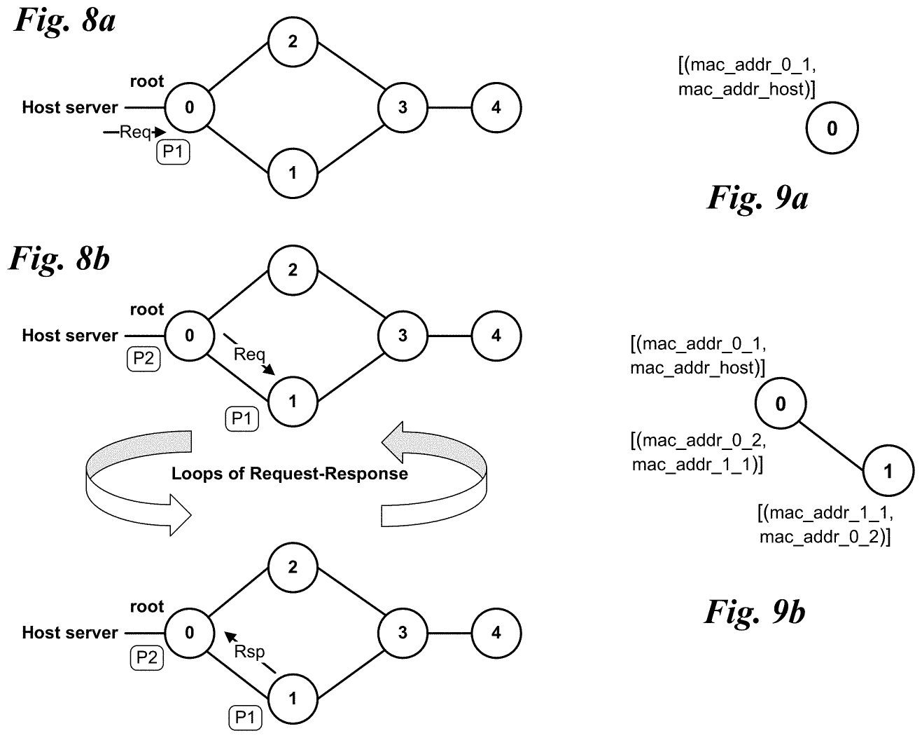

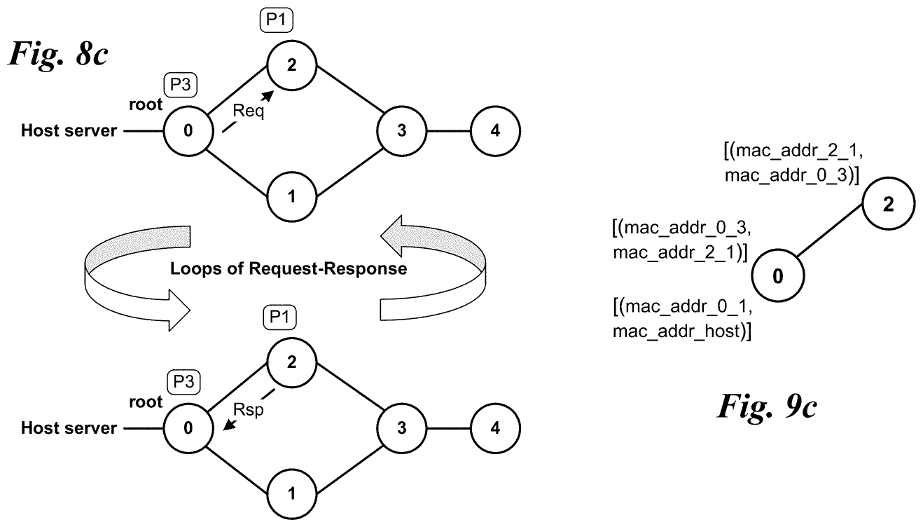

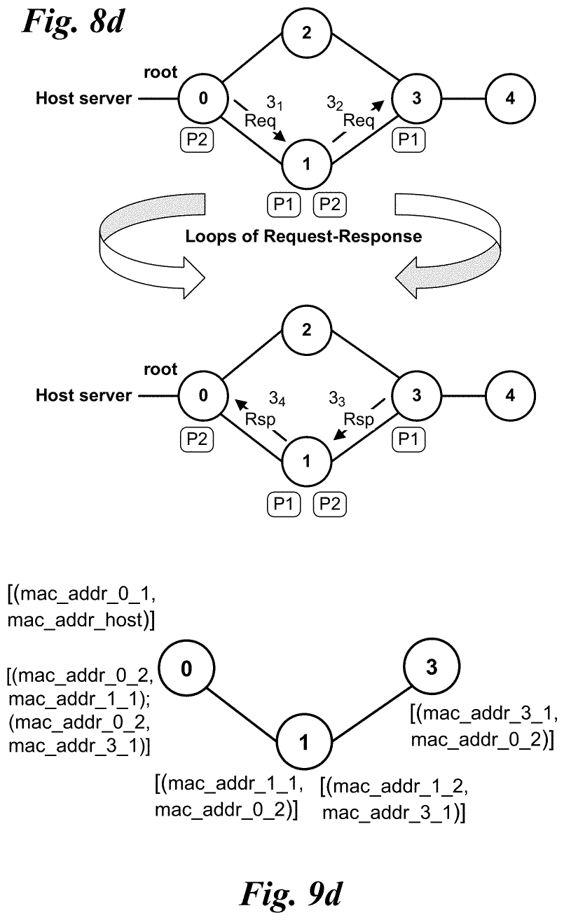

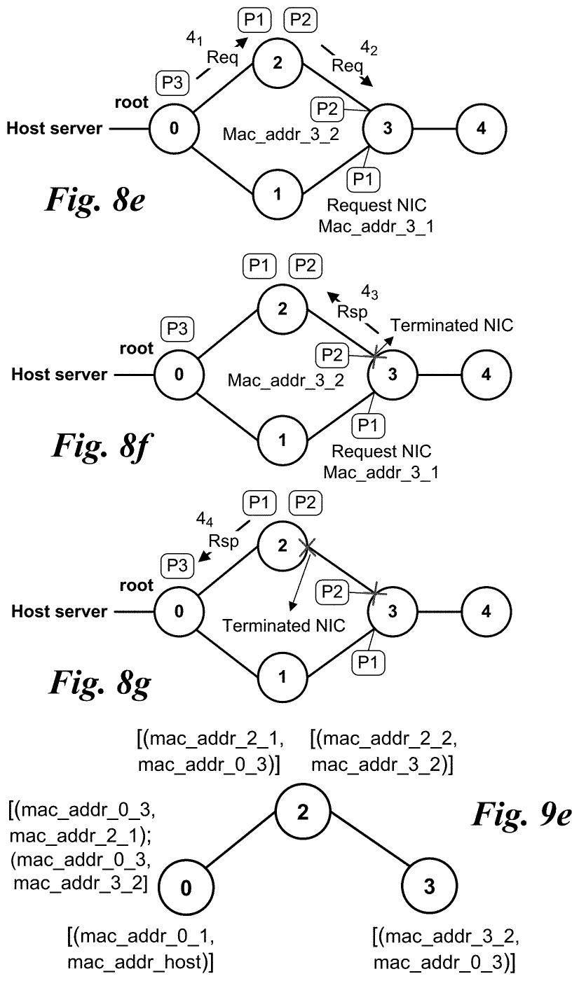

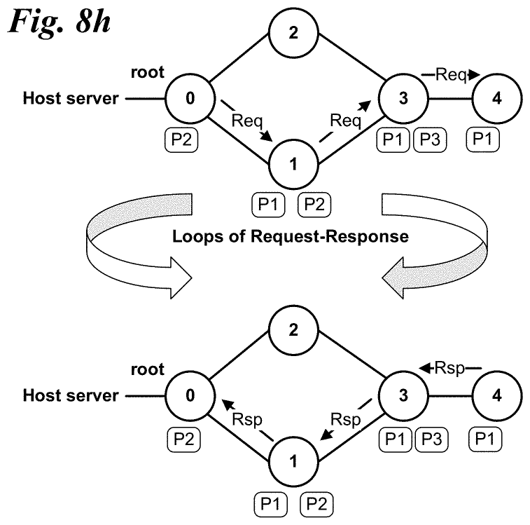

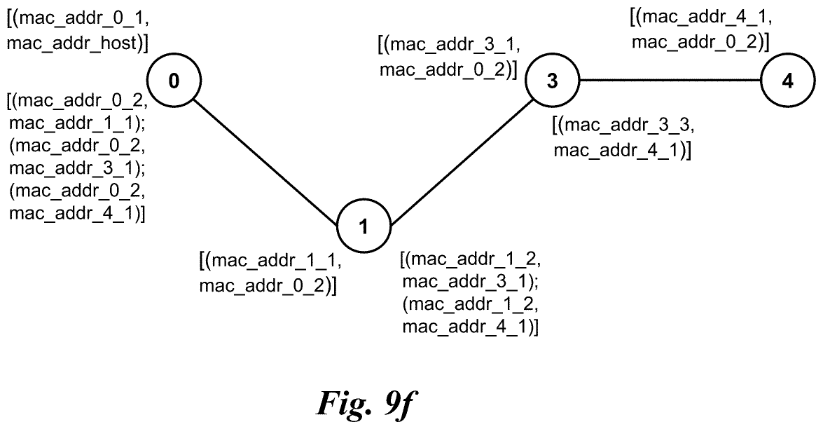

An example discovery process as applied the FPGA topology structure of FIG. 3 is shown in FIGS. 8a-8h and FIGS. 9a-9f. The notation “mac_addr_X_Y” is the MAC address of the “Yth” NIC port of the FPGA with FPGA ID “X”. For example, “mac_addr_0_1” means the MAC address of the NIC port 1 of node 0.

As shown in FIG. 8a, in the first loop of the discovery algorithm, the host server sends a request from its NIC port with MAC address “mac_addr_host” to the root node (node 0). As shown in FIG. 9a, once the request reaches port 1 of the root node, the root node will record it to the MAC address table of port 1 as a key-value item “(mac_addr_0_1mac_addr_host)”. The items in the MAC address tables are in the form of “(Port MAC that receives the request/response, Port MAC that the request/response comes from)”.

As shown in FIG. 8b, in the second loop the root node sends a discovery request from its NIC port 2 to node 1. As shown in FIG. 9b, once the request reaches port 1 of node 1, node 1 will record it to the MAC address table of port 1 as a key-value item “(mac_addr_1_1, mac_addr_0_2)”. Node 1 will then send back the response from its port 1 to the root node. Upon receipt of the response at port 2 of the root node, the root node will record it to the MAC address table of port 2 as a key-value item “(mac_addr_0_2, mac_addr_1_1)”, as also shown in FIG. 9b. This completes the discovery of node 1 by the root node.

In the third loop, the root node will continue the request-response step to discover node 2 based on the BFS algorithm. As shown in FIG. 8c, the root node sends a request from port 3 to port 1 of node 2. Upon receipt of the request, node 2 will record it to the MAC address table of port 1 as a key-value item “(mac_addr_2_1, mac_addr_0_3)”. Node 2 will send back the response from its port 1 to port 3 of the root node. Upon receipt of the response at port 3, the root node will record it to the MAC address table of port 3 as a key-value item “(mac_addr_0_3, mac_addr_2_1)”, as also shown in FIG. 9b. The new entries in the MAC address tables for the root node and node 2 are shown in FIG. 9c.

FIGS. 8d and 9d show operations and MAC address table entries corresponding to discovery of node 3. The root node sends a discovery request from port 2 to port 1 of node 1. Node 1 then forwards the request via its port 2 to port 1 of node 3. Upon receipt of the discovery request, node 3 will add a key-value item “(mac_addr_3_1, mac_addr_0_2)” to its MAC address table. Node 3 will send a response from its port 1 to port 2 of node 1. Upon receipt of the response, node 1 will add a key-value item “(mac_addr_1_2, mac_addr_3_1)” to its MAC address table. Node 1 will then forward the response from its port 1 to port 2 of the root node. The root node will then add a key-value item “(mac_addr_0_2, mac_addr_3_1)” to its MAC address table.

As shown in FIGS. 8e and 9e, the edge from node 2 to node 3 is discovered during the process of discovering node 4. Based on the BFS algorithm, the root node sends a discovery request from port 3 to port 1 of node 2. Node 2 then forwards the request via its port 2 to port 2 of node 3. Upon receipt of the discovery request, node 3 will add a key-value item “(mac_addr_3_2, mac_addr_0_3)” to its MAC address table. Node 3 will then mark its port 2 as the termination port and send a response from its port 2 to port 2 of node 2, as shown in FIGS. 8f Upon receipt of the response, node 2 will add a key-value item “(mac_addr_2_2, mac_addr_3_2)” to its MAC address table. Node 2 will then mark its port 2 as the termination port and forward the response from its port 1 to port 3 of the root node, as shown in FIG. 8g. The root node will then add a key-value item “(mac_addr_0_3, mac_addr_3_2)” to its MAC address table.

As shown in FIG. 8h, the root node will try another path (different from the previous path: 0-2-3) to continuously discover the node 4. The root node sends a discovery request from port 2 to port 1 of node 1. Node 1 then forwards the request via its port 2 to port 1 of node 3. Next, node 3 forwards the request via its port 3 to port 1 of node 4. Upon receipt of the discovery request, node 4 will add a key-value item “(mac_addr_4_1, mac_addr_0_2)” to its MAC address table. Node 3 will then send a response from its port 1 to port 3 of node 3. Upon receipt of the response, node 3 will add a key-value item “(mac_addr_3_3, mac_addr_4_1)” to its MAC address table. Node 3 will then forward the response from its port 1 to port 2 of node 1. Upon receipt of the response, node 1 will add a key-value item “(mac_addr_1_2, mac_addr_4_1)” to its MAC address table. Node 1 will then forward the response from its port 1 to port 2 of the root node. The root node will then add a key-value item “(mac_addr_0_2, mac_addr_4_1)” to its MAC address table.

### Example FPGA PAC

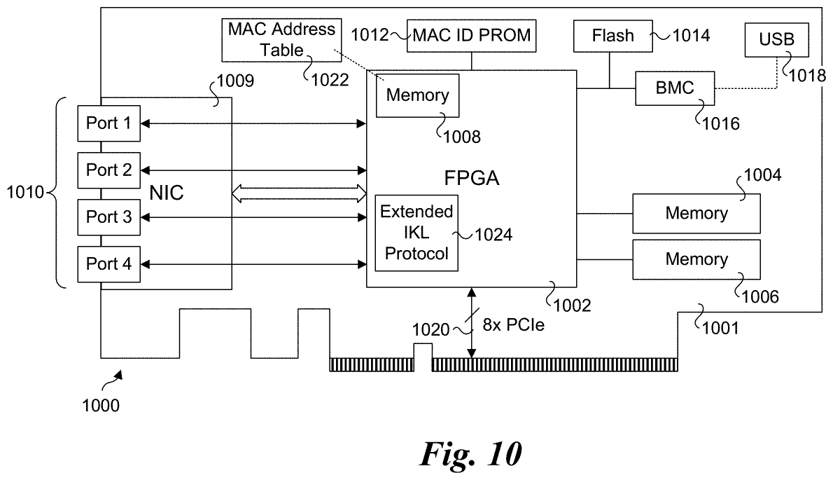

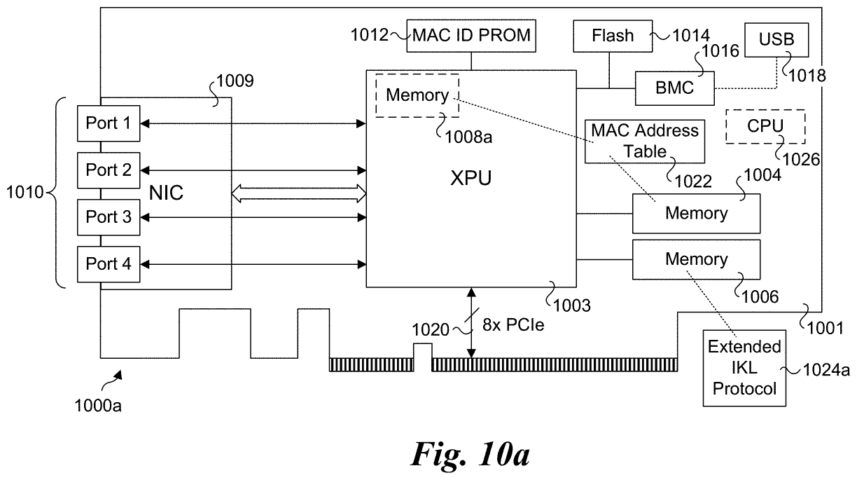

FIG. 10 shows an example FPGA PAC 1000, according to one embodiment. Central to FPGA PAC 1000 is an FPGA 1002 that is coupled to a circuit board 1001. FPGA 1002 is an example of an accelerator programmed to support various functionality including support for inter-kernel communication with other FPGAs. Generally, an FPGA may access data stored in one or more memory devices, such as depicted by memory devices 1004 and 1006. As described below, various types of memory devices may be used, including but not limited to DDR4 and DDR5 DIMMS (Dual Inline Memory Modules). The FPGA may also include onboard memory 1008 in which data may be stored.

In the illustrated embodiment, FPGA PAC 1000 includes a NIC 1009 with four network ports 1010, respectively labeled Port 1, Port 2, Port 3, and Port 4. Data can be transferred between NIC 1009 and FPGA 1002 using separate links per network port 1010 or using a multiplexed interconnect. In one embodiment, NIC 1009 employs a 40GB/s MAC, and each of the four network ports 1010 is a 10GB/s port. In other embodiments, NIC 1009 may employ a MAC with other bandwidths. Also, the illustrated use of four ports is merely exemplary and non-limiting, as a FPGA PAC may have various numbers of network ports.

FPGA PAC 1000 further includes a MAC ID PROM (Programmable Read-only Memory) 1012, flash memory 1014, a baseboard management controller (BMC) 1016, and a USB module 1018. MAC ID PROM 1012 is used to store configuration information, such as the MAC addresses for network ports 1010. The MAC addresses may also be generated by a unique device ID through some Hash algorithms. In some cases, the MAC addresses are stored in memory (e.g., memory 1004, 1006 or 1008). Flash memory 1014 may be used to store firmware and/or other instructions and data in a non-volatile manner.

In the illustrated embodiment, FPGA 1002 has a PCIe interface that is connected to a PCIe edge connector configured to be installed in a PCIe expansion slot. In one embodiment, the PCIe interface comprises an 8 lane (8×) PCIe interface. Other PCIe interface lane widths may be used in other embodiments, including 16 lane (16×) PCIe interfaces.

In the illustrated embodiment, a MAC address table 1022 is stored in a portion of FPGA onboard memory 1008. FPGA onboard memory 1008 may also be used for storing other types of data when FPGA PAC is used as an accelerator during runtime operations.

A portion of the FPGA circuity is programmed to implement the extended IKL protocol disclosed herein, as depicted by an extended IKL protocol block 1024. This block includes logic for implementing various aspects of the extended IKL protocol, including discovery aspects, as well as supporting communication using the IKL protocol.

Generally, a portion of the FPGA 1002 circuitry may be programmed in advance using USB 1018 or another means. For example, circuitry for implementing extended IKL protocol block 1024 may be programmed in advance. As described and illustrated below, multiple FPGA PACs may be implemented in a pooled accelerator “sled” or “drawer.” Under such uses, the FPGA 1002 circuitry may also be programmed via PCI interface 1020 and by one or more network ports 1010.

### Example Data Center Implementation

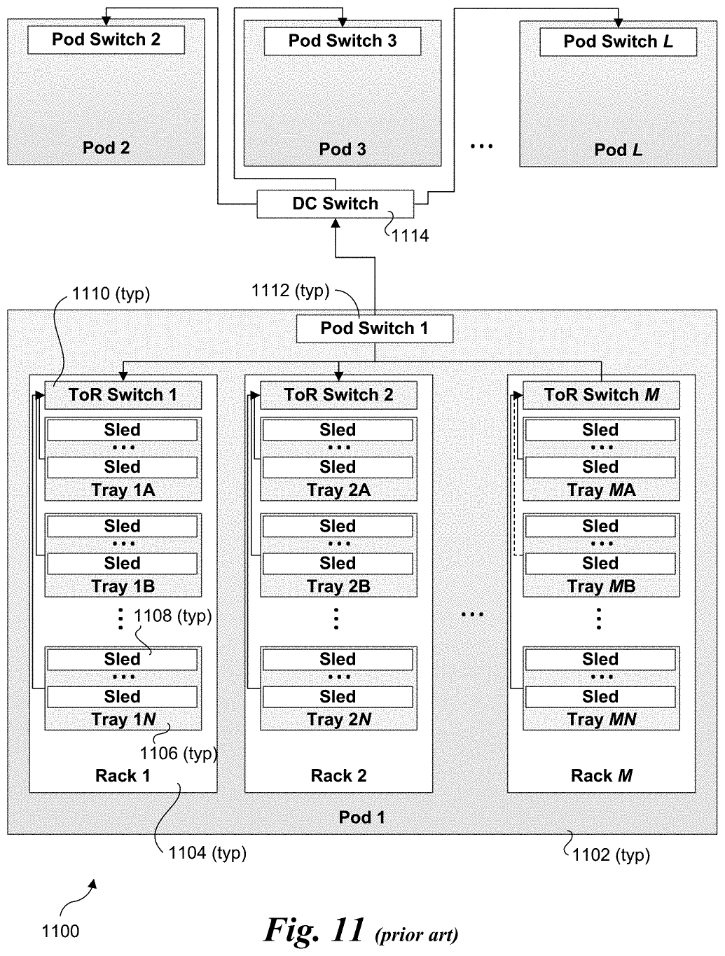

Aspects of the embodiments disclosed herein may be implemented in various types of data center environments. Data centers commonly employ a physical hierarchy of compute, network and shared storage resources to support scale out of workload requirements. FIG. 11 shows a portion of an exemplary physical hierarchy in a data center 1100 including a number L of pods 1102, a number M of racks 1104, each of which includes slots for a number N of trays 1106. Each tray 1106, in turn, may include multiple sleds 1108. For convenience of explanation, each of pods 1102, racks 1104, and trays 1106 is labeled with a corresponding identifier, such as Pod 1, Rack 2, Tray 1B, etc. Trays may also be referred to as drawers, and sleds may also have various forms, such as modules and nodes. In addition to tray and sled configurations, racks may be provisioned using chassis in which various forms of servers are installed, such as blade server chassis and server blades.

Depicted at the top of each rack 1104 is a respective top of rack (ToR) switch 1110, which is also labeled by ToR Switch number. Generally, ToR switches 1110 are representative of both ToR switches and any other switching facilities that support switching between racks 1104. It is conventional practice to refer to these switches as ToR switches whether or not they are physically located at the top of a rack (although they generally are). Alternatively, some implementations include an End of Row (EoR) Switch that are connected to multiple racks instead of TOR switch. As yet another option, some implementations include multiple ToR switches that are configured in a redundant manner, such that is one of the ToR switches fails, another ToR switch is available.

Each Pod 1102 further includes a pod switch 1112 to which the pod's ToR switches 1110 are coupled. In turn, pod switches 1112 are coupled to a data center (DC) switch 1114. The data center switches may sit at the top of the data center switch hierarchy, or there may be one or more additional levels that are not shown. For ease of explanation, the hierarchies described herein are physical hierarchies that use physical LANs. In practice, it is common to deploy virtual LANs using underlying physical LAN switching facilities.

A data center may employ a disaggregated architecture under which one or more of compute, storage, network, and accelerators resources are pooled. A non-limiting example of a disaggregated architecture is Rack Scale Design (RSD) (formerly called Rack Scale Architecture), developed by INTEL® Corporation. Rack Scale Design is a logical architecture that disaggregates compute, storage, network, and accelerator resources and introduces the ability to pool these resources for more efficient utilization of assets. It simplifies resource management and provides the ability to dynamically compose resources based on workload-specific demands.

RSD uses compute, fabric, storage, and management modules that work together to enable selectable configuration of a wide range of virtual systems. The design uses four basic pillars, which can be configured based on the user needs. These include 1) a Pod Manager (PODM) for multi-rack management, comprising firmware and software Application Program Interfaces (APIs) that enable resource and policy management and expose the hardware below and the orchestration layer above via a standard interface; 2) a Pooled system of compute, network, and storage resources that may be selectively composed based on workload requirements; 3) Pod-wide storage built on connected storage uses storage algorithms to support a range of usages deployed as a multi-rack resource or storage hardware and compute nodes with local storage; and 4) a configurable network fabric of hardware, interconnect with cables and backplanes, and management software to support a wide range of cost-effective network topologies, including current top-of-rack switch designs and distributed switches in the platforms.

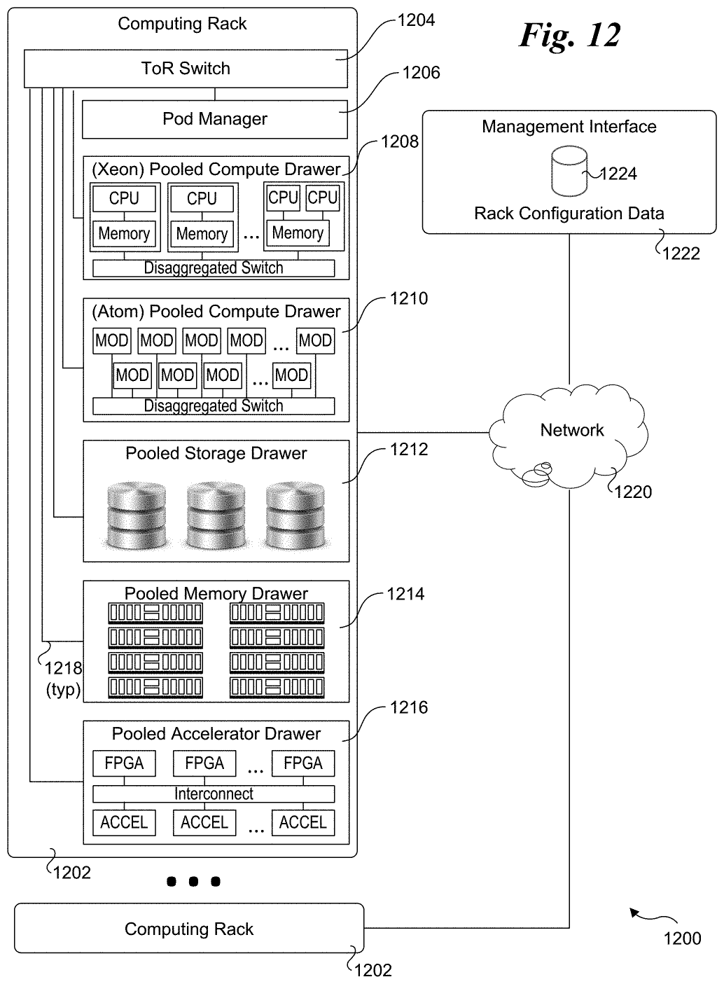

An exemplary RSD environment 1200 is illustrated in FIG. 12. RSD environment 1200 includes multiple computing racks 1202, each including a Top of Rack (ToR) switch 1204, a pod manager 1206, and a plurality of pooled system drawers. Generally, the pooled system drawers may include pooled compute drawers and pooled storage drawers. Optionally, the pooled system drawers may also include pooled memory drawers and pooled Input-Output (IO) drawers. In the illustrated embodiment the pooled system drawers include an INTEL® XEON® pooled computer drawer 1208, and INTEL® ATOM™ pooled compute drawer 1210, a pooled storage drawer 1212, a pooled memory drawer 1214, and a pooled accelerator drawer 1216. Each of the pooled system drawers is connected to ToR switch 1204 via a high-speed link 1218, such as a 40 Gigabit/second (Gb/s) or 100Gb/s Ethernet link or a 100+Gb/s Silicon Photonics (SiPh) optical link. In one embodiment high-speed link 1218 comprises an 800 Gb/s SiPh optical link.

Multiple of the computing racks 1200 may be interconnected via their ToR switches 1204 (e.g., to a pod-level switch or data center switch), as illustrated by connections to a network 1220. In some embodiments, groups of computing racks 1202 are managed as separate pods via pod manager(s) 1206. In one embodiment, a single pod manager is used to manage all of the racks in the pod. Alternatively, distributed pod managers may be used for pod management operations.

RSD environment 1200 further includes a management interface 1222 that is used to manage various aspects of the RSD environment. This includes managing rack configuration, with corresponding parameters stored as rack configuration data 1224.

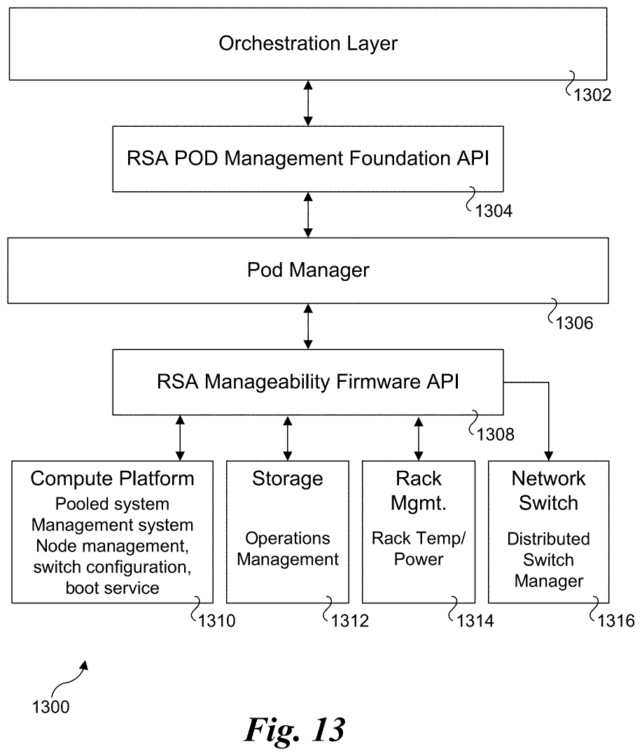

FIG. 13 shows one embodiment of an RSD management architecture 1300. The RSD management architecture includes multiple software and firmware components configured in a layered architecture including an orchestration layer 1302, an RSD pod management foundation API (Application Program Interface), a pod manager 1306, and an RSD manageability firmware API 1308. The bottom layer of RSD management architecture includes a compute platform management component 1310, a storage management component 1312, a rack management component 1314, and a network switch management component 1316.

The compute platform management component 1310 performs operations associated with compute drawers and includes a pooled system, a management system, node management, switch configuration, and boot service. Storage management component 1312 is configured to support operation management of pooled storage drawers. Rack management component 1314 is configured to manage rack temperature and power sub-systems. Network switch management component includes a distributed switch manager.

INTEL® Rack Scale Design is designed to change the focus of platform architecture from single servers to converged infrastructure consisting of compute, network and storage, as discussed above and illustrated in FIG. 12. Management of resources is performed at the rack level and pod level. Focus on management of resources at the rack level also requires management of rack level environments such as power and cooling zones as well as providing a rack level root of trust for relative location information. This role is fulfilled by Rack Management Module (RMM), along with a sub-rack unit (the drawer units in RSD terminology) manager called a Pooled System Management Engine (PSME). The management elements of RSD, RMM and PSMEs are connected to a private network that is not accessible external to the rack.

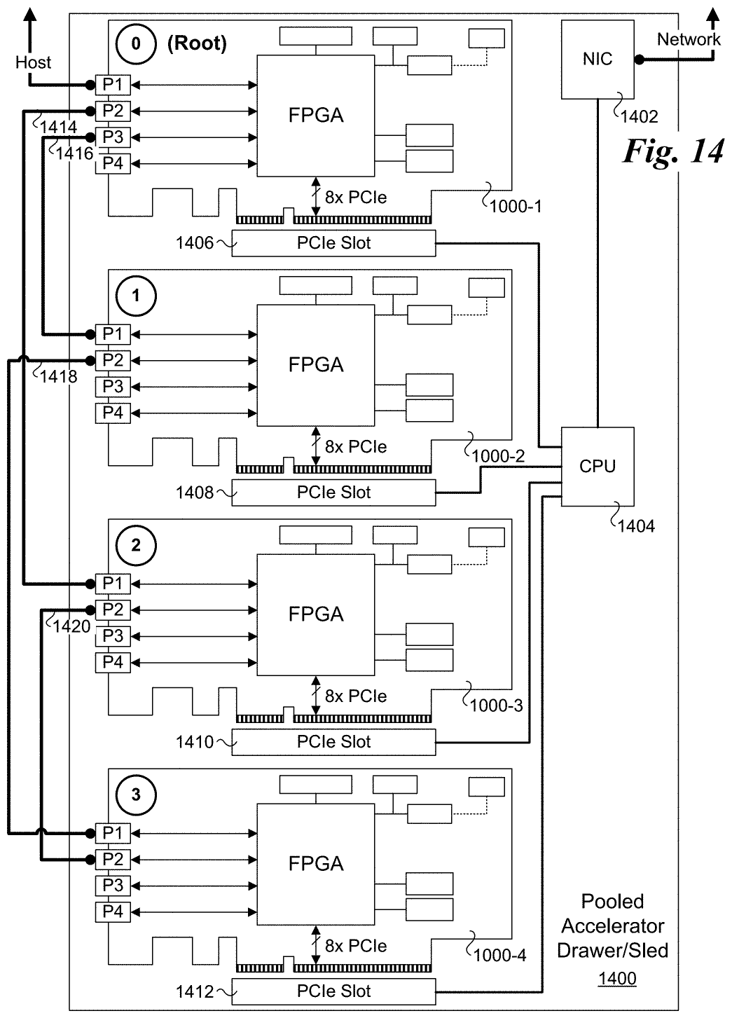

FIG. 14 shows an example of a pooled accelerator drawer or sled 1400. (In alternate embodiments, the pooled accelerator shown in FIG. 14 may be implemented in an accelerator drawer or an accelerator sled; for simplicity, the pooled accelerator will be referred to as an accelerator drawer in the remainder of this disclosure.) For illustrative purposes, pooled accelerator drawer 1400 is depicted as including four FPGA PACs 1000-1, 1000-2, 1000-3, and 1000-4, each having a configuration similar to FPGA PAC 1000 of FIG. 10, and associated with a respective node number 0, 1, 2, and 3, where node 0 is the root node. In practice, the maximum number of FPGA PACs for a given accelerator drawer may vary, depending on the size of the drawer and the size of the FPGA PACs.

Pooled accelerator drawer 1400 includes a NIC 1402 coupled to a CPU 1404. CPU 1404 includes a plurality of PCIe ports (not separately shown) that are coupled to respective PCIe slots 1406, 1408, 1410, and 1412 in which FPGA PACs 1000-1, 1000-2, 1000-3, and 1000-4 are respectively installed. When pooled accelerator drawer 1400 is deployed, NIC 1402 is coupled to a network, such as a private network that is used for management and orchestration purposes. In some embodiments, CPU 1404 is used to implemented PSME functions for pooled accelerator drawer 1400. Generally, CPU 1404 can be any of a CPU, processor or processor/SoC, an embedded processor, a microcontroller, a microengine or manageability engine, etc.

The ports on FPGA PACs 1000-1, 1000-2, 1000-3, and 1000-4 are connected to configure the pooled accelerators (e.g., FPGAs in this example) in a non-start mode. FPGA PAC 1000-1 is the root node, and has its port 1 (labeled P1 in FIG. 14) coupled to a host via a switch, such as an Ethernet switch (not shown). Port 2 (P2) of FPGA PAC 1000-1 is connected to port 1 (P1) of FPGA PAC 1000-2 via a cable 1414. Port 3 of FPGA PAC 1000-1 is connected to port 1 (P1) of FPGA PAC 1000-3 via a cable 1416. Port 2 of FPGA PAC 1000-2 is connected to port 1 (P1) of FPGA PAC 1000-4 via a cable 1418. Port 2 of FPGA PAC 1000-3 is connected to port 2 (P2) of FPGA PAC 1000-4 via a cable 1420.

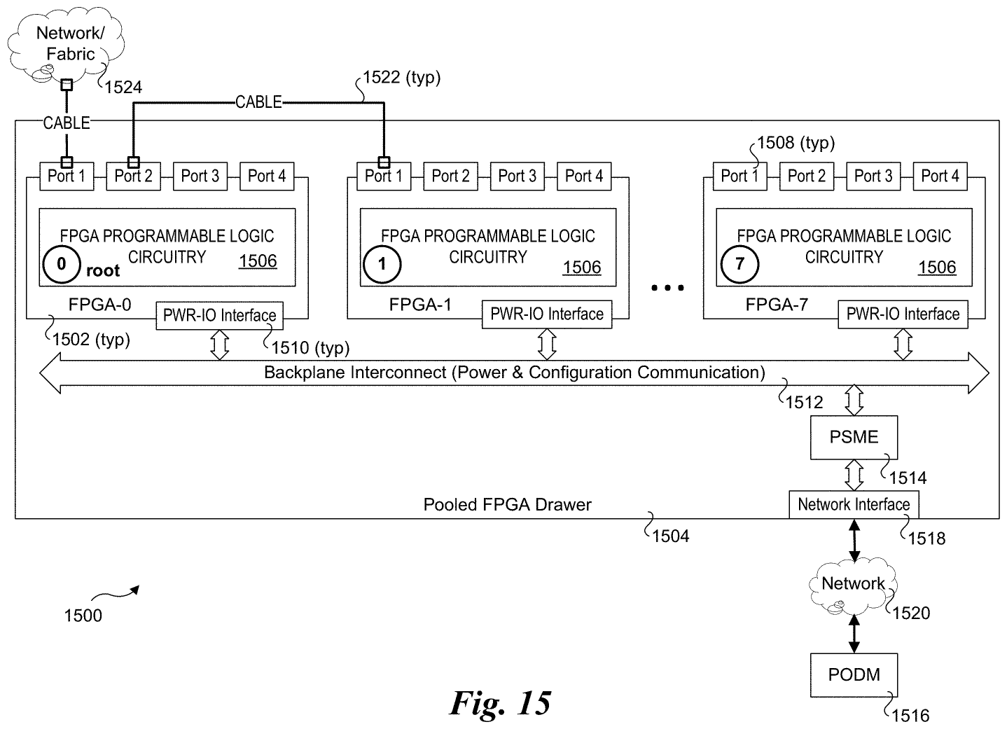

In addition to FPGA PACs or XPU PACs, accelerators may be implemented in pooled accelerator drawers or sleds using discrete accelerator components, such as integrated circuits configured as chips or multi-chip modules. Under configuration 1500 of FIG. 15, eight FPGAs 1502 are installed in a pooled FPGA drawer 1504. Each FPGA 1502 is associated with an FPGA node and includes FPGA programmable logic circuitry 1506 and four IO ports 1508. Each FPGA 1502 further includes a power (PWR)-IO interface 1510 coupled to a backplane interconnect 1512. As above, the term “backplane” is used generically here to cover other configurations, including mid-plane and base-plane configurations. Under alternative configurations the FPGAs illustrated in FIG. 15 may comprise FPGA modules having a connecter that is installed in a mating slot/connector in pooled FPGA drawer that is coupled to backplane interconnect 1512.

In the embodiment illustrated in FIG. 15, backplane interconnect 1512 is depicted as providing power and configuration communication. The configuration communication portion of backplane interconnect 1512 includes circuitry and wiring for facilitating configuration of the FPGAs, including downloading FPGA bitstreams to configure FPGA programmable logic circuitry in each FPGA. In the illustrated embodiment, FPGA configuration is implemented via use of a PSME 1514 that communicates with a PODM 1516 via a network interface 1518 and network 1520. In one embodiment, network 1520 is a private network that is separate and apart from the network or fabric 1524 used for data communication between drawers and across the data center.

A portion of IO ports 1508 for the FPGAs 1502 may be used to communicate with external FPGA consumers and used for chaining between FPGAs 1502 within pooled FPGA drawer 1504. In one embodiment, IO ports 1508 are mounted on FPGA cards or modules and are configured to receive cable connectors to enable cables to be coupled both to an external FPGA consumer and cables between FPGA 1502, as depicted by a cable 1522. In an alternative embodiment (not shown), an FPGA PWR-IO interface includes pins or traces to carry signals to a physical cable port that is mounted to the pooled FPGA drawer. This would generally include wiring in a circuit board or the like between the connector half on the main board or backplane of the pooled FPGA drawer and the physical cable port. As another alternative configuration, FPGAs 1502 may have less than four IO ports. In addition, a portion of the IO ports on an FPGA may be used for internal cabling, wherein the IO ports are not exposed to receive cables external to the pooled FPGA drawer. In one embodiment, the IO Port are coupled to multiplexer circuitry (not shown) that enables signals to be routed to selected circuitry and/or interfaces on the FPGAs.

In addition to use of accelerators comprising FPGAs, to Other Processing Units (collectively termed XPUs) including one or more of Graphic Processor Units (GPUs) or General Purpose GPUs (GP-GPUs), Tensor Processing Unit (TPU) Data Processor Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of FPGAs, this is merely exemplary and non-limiting. Generally, any type of XPU may be used in place of an FPGA in the illustrated embodiments. Moreover, as used in the following claims, the term “accelerator unit” is used to generically cover FPGAs and various other forms of XPUs.

An example use of an XPU is shown in FIG. 10a, which depicts an accelerator card 1000a in which an XPU 1003 is used in place of the FPGA 1002 in FIG. 10. Components in FIGS. 10 and 10a with like references numbers are similar, so the following discussion will focus on the differences between FPGA PAC 1000 and accelerator card 1000a.

Since most XPUs that are not FPGAs do not have programmable logic, the logic for implementing Extended IKL protocol 1024a is different than used for Extended IKL protocol 1024 discussed above. Depending on the type of XPU, Extended IKL protocol 1024a may be implemented using an embedded software layer or interface comprising instructions that are executed on the XPU or executed on an optional CPU 1026, which is representative of various types of processor units, such as an embedded processor, a microcontroller, a microengine or manageability engine, etc. The instructions may reside in flash 1014 or may be downloaded and installed in memory device 1004 or 1006. In cases where an XPU includes onboard memory 1008a, the instructions may be loaded into and executed from memory 1008a. Likewise, the MAC address table may be stored in onboard memory 1008a if such exists, or may be stored in memory device 1004 or 1006.

### Support for Accelerated Microservices

In one aspect, the principles and teachings herein may be extended to accelerators in general and used for microservices XPU-to-XPU communication. In one embodiment, the extended IKL protocol includes one or more fields (in addition to those shown and discussed above) pertaining to microservice resources available on different XPUs (or accelerator cards more generally). Generally, the same discovery algorithm and process described above may be used to determine the XPU topology and build the MAC address tables. During the process, the microservice resources are also gathered and returned to the host. This enables the host to determine which accelerators (XPUs) support what accelerated microservices and direct corresponding workloads to those accelerators.

The use of NICs in the description and Figures herein is representative of hardware IO communication components that may be used for implementing direct links (aka point-to-point links) between accelerators such as FPGAs. In particular, the direct links are not limited to network links such as Ethernet, but more generally may employ various types of high speed serial interconnect (HSSI), such as but not limited to Interlaken and Serial Lite (e.g., Serial Lite III).

As used herein, a volatile memory is memory whose state (and therefore the data stored in it) is indeterminate if power is interrupted to the device. Dynamic volatile memory requires refreshing the data stored in the device to maintain state. One example of dynamic volatile memory includes DRAM, or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in Sep. 2012 by JEDEC), DDR4E (DDR version 4), LPDDR3 (Low Power DDR version3, JESD209-3B, Aug. 2013 by JEDEC), LPDDR4) LPDDR version 4, JESD209-4, originally published by JEDEC in Aug. 2014), DDR5 (DDR version 5), initial specification JESD79-5, Jul. 2020 by JEDEC), WIO2 (Wide Input/output version 2, JESD229-2 originally published by JEDEC in Aug. 2014), HBM (High Bandwidth Memory, JESD325, originally published by JEDEC in Oct. 2013, LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

As discussed above, various aspects of the embodiments herein may be facilitated by corresponding software and/or firmware components and applications, such as software and/or firmware executed by an embedded processor or the like. Thus, embodiments of this invention may be used as or to support a software program, software modules, firmware, and/or distributed software executed upon some form of processor, processing core or embedded logic a virtual machine running on a processor or core or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (i.e., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

Various components referred to above as processes, servers, or tools described herein may be a means for performing the functions described. The operations and functions performed by various components described herein may be implemented by software running on a processing element, via embedded hardware or the like, or any combination of hardware and software. Such components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of ” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An accelerator apparatus, comprising
a circuit board;
an accelerator unit, coupled to the circuit board;
a plurality of input-output (IO) ports, operatively coupled to the accelerator unit; and
embedded logic, implemented in the accelerator unit or in a component coupled to the accelerator unit and coupled to the circuit board,
wherein the accelerator apparatus is configured to be implemented in an accelerator pool comprising a plurality of accelerator units that are interconnected via links coupled between IO ports on the accelerator apparatuses to implement a non-star mode,
wherein the embedded logic is configured to implement an inter-kernel communication protocol comprising a data transmission protocol built over a Media Access Control (MAC) layer and transported over the links, and wherein the inter-kernel communication protocol provides support for command transmission including a discovery command used in a discovery algorithm to determine a topology of the non-star mode via discovery requests and responses transmitted between the plurality of accelerator apparatuses using the inter-kernel communication protocol.

2. The accelerator apparatus of claim 1, wherein the accelerator unit comprises a Field Programmable Gate Array (FPGA).

3. The accelerator apparatus of claim 2, wherein the inter-kernel communication protocol is implemented via a portion of programmed circuitry in the FPGA.

4. The accelerator apparatus of claim 2, wherein the accelerator unit in each of the plurality of accelerator apparatuses comprises an FPGA, and the discovery algorithm enables collection of FPGA storage related information for the plurality of accelerator apparatuses.

5. The accelerator apparatus of claim 1, wherein the accelerator apparatus is configured to be implemented as a root node that includes a first IO port communicatively coupled to a switch in a network to which a host is coupled, and second and third IO ports directly linked to respective IO ports on second and third accelerator apparatuses implemented as second and third nodes in the non-star mode.

6. The accelerator apparatus of claim 5, wherein each of the second and third nodes is connected to at least one other node that is not the root node, and wherein the root node is configured to:
send a plurality of discovery requests that are forwarded to each of a plurality of non-root nodes in the accelerator pool;
receive a plurality of discovery responses originating from the plurality of non-root nodes that are forwarded to IO ports on the root node, wherein a discovery response includes a MAC address of an IO port from which the discovery response originated; and
generate a MAC address table including a plurality of entries comprising a (key, value) pair comprising the MAC address of the IO port on the root node at which a discovery response is received and the MAC address of the IO port in the discovery response.

7. The accelerator apparatus of claim 6, wherein the root node is enabled, via the discovery algorithm, to determine a topology of the accelerator units in the accelerator pool.

8. The accelerator apparatus of claim 1, further comprising a Peripheral Component Interconnect Express (PCIe) interface configured to be installed in a PCIe slot in a pooled accelerator drawer, sled, or chassis comprising a plurality of respective PCIe slots in which other respective accelerator apparatuses are installed or configured to be installed.

9. The accelerator apparatus of claim 1, wherein the accelerator apparatus is configured to be implemented as a first non-root node in an accelerator pool comprising a plurality of non-root nodes and a single root node, and wherein the first non-root node is configured to:
receive a discovery request sent from an IO port on a root node and identifying a MAC address of the IO port on the root node;
generate a MAC address table entry comprising a (key, value) pair comprising the MAC address of the IO port on the root node and a MAC address of an IO port on the first non-root mode at which the discovery request is received; and
return a discovery response to the root node.

10. The accelerator apparatus of claim 1, wherein the accelerator unit comprises a Graphic Processor Unit (GPU), a General Purpose GPU (GP-GPU), a Tensor Processing Unit (TPU), a Data Processor Unit (DPU), an Infrastructure Processing Unit (IPU), an Artificial Intelligence (AI) processor, an AI inference unit or a Vector Processing Unit (VPU).

11. The accelerator apparatus of claim 1, wherein the inter-kernel communication protocol is an extension to an inter-kernel link (IKL) protocol.

12. A method implemented by an accelerator pool including a plurality of accelerators comprising nodes configured in a non-star mode under which accelerators in the accelerator pool are interconnect by a plurality of links coupled between input-output (IO) ports to which the accelerators are operatively coupled, the method comprising:
sending discovery requests from a root node to be forwarded to non-root nodes in the accelerator pool, the discovery requests transmitted via links coupled between the plurality of nodes using an inter-kernel communication protocol comprising a data transmission protocol built over a Media Access Control (MAC) layer and transported over the links;
receiving, at the root node, discovery responses sent from the non-root nodes and forwarded to the root node; and
generating a MAC address table at the root node including a plurality of (key, value) pair entries comprising the MAC address of an IO port from which a discovery request was sent and the MAC address of an IO port of a non-root node from which a discovery response corresponding to the discovery request was sent.

13. The method of claim 12, further comprising:
at a first non-root node,
receiving, at a first IO port on the non-root node having a first MAC address, a first discovery request destined for the non-root node, the discovery request comprising a second MAC address of an IO port on the root node from which the discovery request was sent;
generating a MAC address table entry comprising a (key, value) pair including the first MAC address and the second MAC address; and
sending a discovery response via the first IO port to be forwarded to the root node indicating the first non-root node has been discovered.

14. The method of claim 13, further comprising:
at the first non-root node,
receiving, at the first IO port on the non-root node, a second discovery request destined for a second non-root node;
forwarding the discovery request via a link coupled a second IO port on the first non-root node having a third MAC address;
receiving a discovery response sent from the second non-root node and including a fourth MAC address of an IO port on the second non-root node from which the discovery response was sent;
generating a MAC address table entry comprising a (key, value) pair including a third MAC address and the fourth MAC address; and
sending the discovery response via the first IO port on the first non-root node to be forwarded to the root node.

15. The method of claim 12, further comprising:
determining, by means of the discovery request responses, a topology of the nodes in the accelerator pool; and
determining a shortest path from the root node to each of the non-root nodes.

16. The method of claim 12, wherein the plurality of accelerators are Field Programmable Gate Arrays (FPGAs), and wherein a discovery response includes information associated with one or more regions in a storage space for an FPGA associated with the node sending the discovery response.

17. An apparatus comprising:
a drawer, sled or chassis; and
a plurality of accelerator installed in the drawer, sled, or chassis, each accelerator operatively coupled to one or more input-output (IO) ports and comprising a node, wherein pairs of IO ports coupled to respective accelerators are linked to form a non-star mode configuration including a root node and a plurality of non-root nodes,
wherein each of the accelerators is configured to implement an inter-kernel communication protocol comprising a data transmission protocol built over a Media Access Control (MAC) layer and transported over the links, and wherein the inter-kernel communication protocol provides support for command transmission including a discovery command used in a discovery algorithm to determine a topology of the non-star mode via discovery requests and responses transmitted between the plurality of accelerator using the inter-kernel communication protocol.

18. The apparatus of claim 17, wherein the plurality of accelerators comprises one of more of a Graphic Processor Unit (GPU), a General Purpose GPU (GP-GPU), a Tensor Processing Unit (TPU), a Data Processor Unit (DPU), an Infrastructure Processing Unit (IPU), an Artificial Intelligence (AI) processor, an AI inference unit, a Field Programmable Gate Array (FPGA) and a Vector Processing Unit (VPU).

19. The apparatus of claim 18, wherein the accelerators are installed on accelerator cards that are installed in respective slots of a board disposed in the drawer, sled, or chassis.

20. The apparatus of claim 17, wherein the accelerators comprise Programmable Gate Array (FPGA), and wherein the discovery algorithm enables collection of FPGA storage related information for the FPGAs.
